(19) United States
(12) Patent Application Publication
(10) Pub. No.: US 2026/0164665 A1
(43) Pub. Date: Jun. 11, 2026

(54) SEMICONDUCTOR DEVICE, ELECTRONIC APPARATUS INCLUDING THE SAME, AND METHOD OF MANUFACTURING THE SEMICONDUCTOR DEVICE

(71) Applicants: Samsung Electronics Co., Ltd., Suwon-si, Gyeonggi-do (KR); SEOUL NATIONAL UNIVERSITY R&DB FOUNDATION, Seoul (KR)

(72) Inventors: Minhyun LEE, Suwon-si (KR); Cheolseong HWANG, Seoul (KR); Sahngik MUN, Seoul (KR); Seungdam HYUN, Suwon-si (KR); Seokhoon CHOI, Suwon-si (KR); Hoseok HEO, Suwon-si (KR)

(73) Assignees: Samsung Electronics Co., Ltd., Suwon-si, Gyeonggi-do (KR); SEOUL NATIONAL UNIVERSITY R&DB FOUNDATION, Seoul (KR)

(21) Appl. No.: 19/410,726

(22) Filed: Dec. 5, 2025

(30) Foreign Application Priority Data
Dec. 9, 2024 (KR) 10-2024-0181994
Mar. 6, 2025 (KR) 10-2025-0029206

(51) Int. Cl. H10B 43/35; H10B 43/10; H10B 43/27

(52) U.S. Cl. CPC H10B 43/35; H10B 43/10; H10B 43/27

(57) ABSTRACT

Provided are a semiconductor device, an electronic apparatus including the same, and a method of manufacturing the semiconductor device. The semiconductor device may include a plurality of gate electrodes and a plurality of spacer layers alternately stacked and including a channel hole penetrating therethrough, a gate stack including at least one layer on an inner side of the channel hole, a channel layer on the gate stack, a pillar on the channel layer, and a source electrode and a drain electrode which are electrically connected to the channel layer. The channel layer may include material A and oxygen. The material A may include at least one of tin, cobalt, steel, nickel, copper, and vanadium.

### CROSS-REFERENCE TO RELATED APPLICATION

This application is based on and claims priority under 35 U.S.C. § 119 to Korean Patent Application Nos. 10-2024-0181994 and 10-2025-0029206, respectively filed on Dec. 9, 2024 and Mar. 6, 2025 in the Korean Intellectual Property Office, the disclosures of which are incorporated by reference herein in their entirety.

### BACKGROUND

### 1. Field

The disclosure relates to a semiconductor device including an ambipolar channel layer, an electronic apparatus including the semiconductor device, and a method of manufacturing the semiconductor device.

### 2. Description of the Related Art

As existing hard disks have been replaced with solid state drives (SSD), NAND flash memory devices, which are non-volatile memory devices, are now widely used. In accordance with the miniaturization and higher integration of non-volatile memory devices, vertical NAND flash memory devices having a structure in which a plurality of memory cells are stacked have been developed.

Recently, as memory device may have higher integration and lower power consumption, there has been a growing interest in overcoming issues concerning higher program/erase voltages, smaller memory window, data retention, etc. In non-volatile memory devices, an increase in the stacking number of memory cells and a decrease in height thereof may cause a charge migration between the memory cells, which may degrade the charge retention properties of the memory cells. Performance of the non-volatile memory devices may be improved by using a channel including an oxide semiconductor having better electrical characteristics compared to polycrystalline silicon.

### SUMMARY

Provided is a semiconductor device including an ambipolar channel layer.

Provided is an electronic apparatus including a semiconductor device including an ambipolar channel layer.

Provided is a method of manufacturing a semiconductor device including an ambipolar channel layer.

Additional aspects will be set forth in part in the description which follows and, in part, will be apparent from the description, or may be learned by practice of the presented embodiments of the disclosure.

According to an example embodiment of the disclosure, a semiconductor device may include a gate electrode and a spacer layer, which may be alternately stacked to provide a plurality of gate electrodes and a plurality of spacer layers alternately stacked, the plurality of gate electrodes and the plurality of spacer layers defining a channel hole penetrating through the plurality of gate electrodes and the plurality of spacer layers; a gate stack including at least one layer on an inner side of the channel hole; a channel layer on the gate stack; a pillar on the channel layer; and a source electrode and a drain electrode which may be electrically connected to the channel layer. The channel layer may include material A and oxygen. The material A may include at least one of tin, cobalt, steel, nickel, copper, and vanadium. The pillar may include an aluminum oxide layer in contact with the channel layer.

In some embodiments, the pillar may further include a silicon oxide layer on the aluminum oxide layer.

In some embodiments, a material of the channel layer may include A₍₁₋ₓ₎Oₓ. In A₍₁₋ₓ₎Oₓ, the material A may include at least one of tin, cobalt, steel, and nickel, and x may be in a range from 0.4 to 0.6.

In some embodiments, x may in a range from 0.47 to 0.53.

In some embodiments, a material of the channel layer may include A₍₁₋ₓ₎Oₓ. In A₍₁₋ₓ₎Oₓ, the material A may include copper, and x may be in a range from 0.27 to 0.39.

In some embodiments, a material of the channel layer may include A₍₁₋ₓ₎Oₓ. In A₍₁₋ₓ₎Oₓ, the material A may include vanadium, and x may be in a range from 0.55 to 0.79.

In some embodiments, the source electrode and the drain electrode may have a work function greater than 0 eV and less than or equal to 5 eV.

In some embodiments, the channel may further include a dopant at a content of 5 at % or less.

In some embodiments, the dopant may include at least one of Ni, Cu, Ge, Cd, Sn, and Pb.

In some embodiments, the at least one layer of the gate stack may include a charge-tunneling layer on the channel layer, a charge trap layer on the charge-tunneling layer, and a charge-blocking layer on the charge trap layer.

In some embodiments, at least one of layer of the gate stack may include a ferroelectric material layer.

According to an example embodiment of the disclosure, an electronic apparatus may include a host, a semiconductor device, and a memory controller configured to, in response to a request from the host, control the semiconductor device for at least one of data reading from the semiconductor device and data writing to the semiconductor device.

The semiconductor device may include a gate electrode and a spacer layer, which may be alternately stacked to provide a plurality of gate electrodes and a plurality of spacer layers alternately stacked, the plurality of gate electrodes and the plurality spacer layers defining a channel hole penetrating through the plurality of gate electrodes and the plurality spacer layers; a gate stack including at least one layer on an inner side of the channel hole; a channel layer on the gate stack; a pillar on the channel layer; and a source electrode and a drain electrode which may be electrically connected to the channel layer.

The channel layer may include material A and oxygen. The material A may include at least one of tin, cobalt, steel, nickel, copper, and vanadium. The pillar may include an aluminum oxide layer in contact with the channel layer.

According to an example embodiment of the disclosure, a method of manufacturing a semiconductor device may include alternately stacking a spacer layer and a sacrificial layer to provide a plurality of spacer layers and a plurality of sacrificial layers alternately stacked; forming a channel hole to penetrate through the plurality of spacer layers and the plurality of sacrificial layers; forming a gate stack on an inner side of the channel hole; forming a channel layer on the gate stack; forming a pillar on the channel layer; removing the plurality of sacrificial layers; and forming a plurality of gate electrodes in spaces from which the plurality of sacrificial layers have been removed. The channel layer may include material A and oxygen. The material A may include at least one of tin, cobalt, steel, nickel, copper, and vanadium, and the pillar may include an aluminum oxide layer in contact with the channel layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a semiconductor device according to an embodiment;

FIG. 2A is a cross-sectional view taken along line A-A′ of FIG. 1;

FIG. 2B is a diagram illustrating an example in which the semiconductor device of FIG. 2A further includes a second charge-blocking layer and a silicon oxide layer;

FIG. 3 is a diagram illustrating an example in which a gate stack is changed to a single ferroelectric material layer in FIG. 2A;

FIG. 4 is a diagram illustrating an example in which the gate stack is changed to other layers in FIG. 2A;

FIG. 5 shows a threshold voltage shift according to stress time of a semiconductor device, according to an embodiment;

FIG. 6 shows a mobility and an on/off ratio according to a deposition temperature of a semiconductor device, according to an embodiment;

FIG. 7 shows a drain current according to a gate voltage of a semiconductor device, according to an embodiment;

FIGS. 8A to 8F are diagrams illustrating a method of manufacturing a semiconductor device according to an embodiment;

FIGS. 9A to 9D are diagrams illustrating a method of manufacturing a semiconductor device according to another embodiment;

FIG. 10 is a circuit diagram to which a vertical semiconductor device according to an embodiment is applied;

FIG. 11 is a schematic block diagram of a display apparatus including a display driver integrated circuit (DDI) according to an embodiment;

FIG. 12 is a block diagram of an electronic apparatus according to an embodiment;

FIG. 13 is a block diagram of an electronic apparatus according to an embodiment;

FIG. 14 is a schematic conceptual diagram illustrating a device architecture applicable to an electronic apparatus according to an embodiment; and

FIG. 15 is a schematic conceptual diagram illustrating a device architecture applicable to an electronic apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a semiconductor device according to various embodiments, an electronic apparatus including the same, and a method of manufacturing the semiconductor device will be described in detail with reference to the accompanying drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” a component, another component may be further included, rather than excluding the existence of the other component, unless otherwise described. Sizes or thicknesses of components in the drawings may be arbitrarily exaggerated for convenience of explanation. Further, when a certain material layer is described as being arranged on a substrate or another layer, the material layer may be in contact with the other layer, or there may be a third layer between the material layer and the other layer. In embodiments, materials constituting each layer are provided merely as an example, and other materials may also be used.

Moreover, the terms “part,” “module,” etc. refer to a unit processing at least one function or operation, and may be implemented by a hardware, a software, or a combination thereof.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail. Furthermore, the connecting lines, or connectors shown in the various figures presented are intended to represent examples of functional relations and/or physical or logical couplings between the various elements. It should be noted that many alternative or additional functional relations, physical connections or logical connections may be present in a device.

The use of the terms “a” and “an” and “the” and similar referents in the context of describing embodiments (especially in the context of the following claims) are to be construed to cover both the singular and the plural.

Also, the steps of all methods described herein can be performed in any suitable order unless otherwise indicated herein or otherwise clearly contradicted by context. The use of any and all example language (e.g., “such as”) provided herein, is intended merely to better illuminate technical ideas and does not pose a limitation on the scope of embodiments unless otherwise claimed.

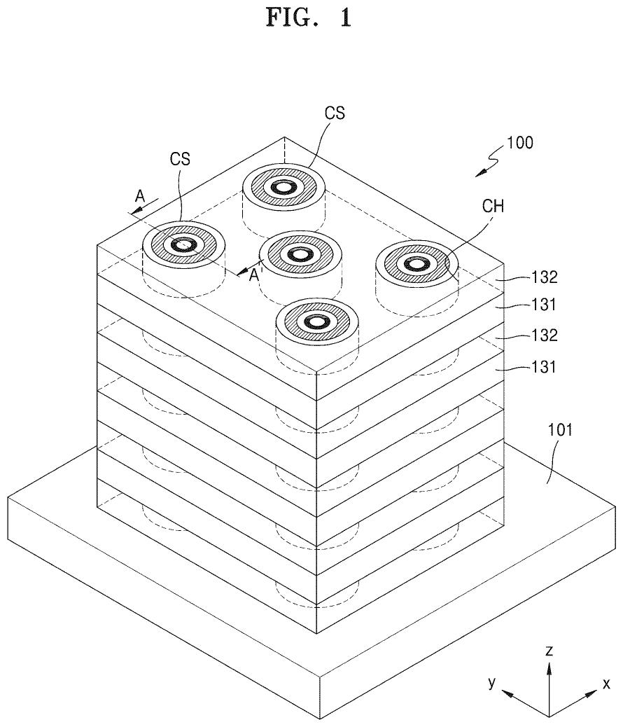

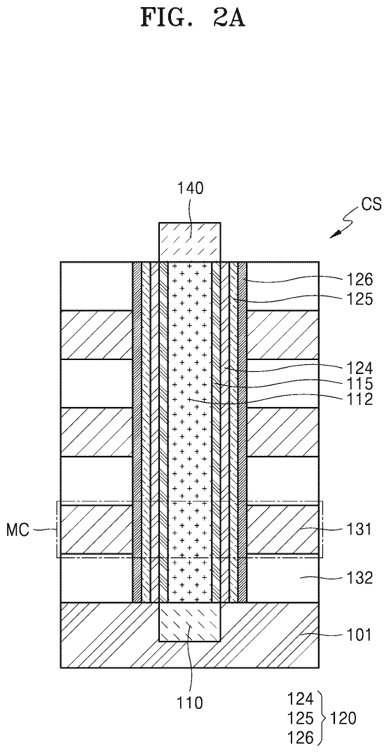

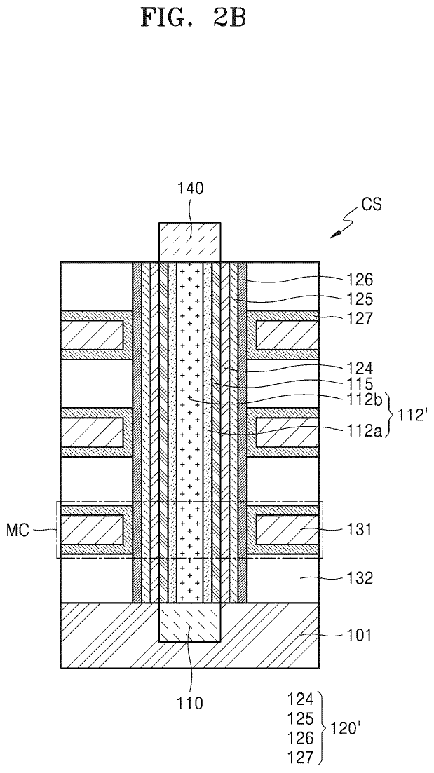

FIG. 1 is a schematic perspective view of a semiconductor device according to an embodiment, and FIG. 2A is a cross-sectional view taken along the line A-A′ in FIG. 1.

Referring to FIG. 1, a semiconductor device 100 may include a plurality of cell strings CS arranged on a substrate 101. Each of the cell strings CS may extend in a first direction (z axis direction) with respect to the substrate 101. The first direction may be a direction perpendicular to the substrate 101. The plurality of cell strings CS may be arranged on the substrate 101 in various forms. A gate electrode 131 and a spacer layer 132 may be alternately stacked on the substrate 101 to provide a plurality of gate electrodes 131 and a plurality of spacer layers 132 alternately stacked. A channel hole CH may penetrate a stack of the plurality of gate electrodes 131 and the plurality of spacer layers 132 in the first direction (z axis direction) perpendicular to the substrate 101. The channel hole CH may have, for example, a circular cross-section. However, the shape of the cross-section of the channel hole CH is not limited thereto.

In the cell string CS, parts other than the gate electrodes 131 and the spacer layers 132 may have a stacked structure of a plurality of cylindrical shells in the channel hole CH. However, the structure of the cell string CS is not limited thereto, and the cell string CS may have other shapes and structures.

Referring to FIG. 2A, a gate stack 120 and a channel layer 115 may be arranged in the channel hole CH. The gate stack 120 may include at least one layer. The gate stack 120 may include, for example, a charge-tunneling layer 124, a charge trap layer 125, and a first charge-blocking layer 126. The charge-tunneling layer 124 may be arranged on the channel layer 115, and the channel layer 115 may be arranged on a pillar 112.

Each cell string CS may include a plurality of memory cells MC stacked in the direction perpendicular to the substrate 101 (z axis direction). The memory cell MC may be a base unit cell where data is written or deleted.

The substrate 101 may include a single-crystal semiconductor substrate (e.g., single-crystal silicon substrate), a compound semiconductor substrate, or a semiconductor-on-insulator (SOI) substrate (e.g., silicon on insulator substrate); however, the disclosure is not limited thereto. In addition, the substrate 101 may further include, for example, an impurity area due to doping, an electronic device such as a transistor, or a periphery circuit configured to select and control memory cells storing data.

The pillar 112 may include an aluminum oxide layer. The aluminum oxide layer may be in direct contact with the channel layer 115. The aluminum oxide layer may have a cylindrical structure. The aluminum oxide layer may have a crystal structure. Each of the channel layer 115, the charge-tunneling layer 124, and the charge trap layer 125 may extend in the same direction with respect to the substrate 101 and may be shared by the plurality of memory cells MC.

The channel layer 115 may include material A and oxide, and the material A may include at least one of tin (Sn), cobalt (Co), steel (Fe), nickel (Ni), copper (Cu), and vanadium (V). The channel layer 115 may include A₍₁₋ₓ₎Oₓ where x may be in a range from 0.25 to 0.8. When the material A includes at least one of Sn, Co, and Ni, x may be in a range from 0.4 to 0.6. In some embodiments, x may be in a range from 0.47 to 0.53. When the material A includes Cu, x may be in a range from 0.27 to 0.39. When the material A includes V, x may be in a range from 0.55 to 0.79. The channel layer 115 may include an amorphous or crystalline substance.

In the semiconductor device 100, electron flow may occur when data is stored, hole flow may occur when data is erased, and electron flow may occur when data is read. The channel layer 115 may have both p-type characteristics and n-type characteristics. Thus, electrons and holes may selectively migrate through the channel layer 115 which is ambipolar. Information may be stored by injecting electrons into the charge trap layer 125, and information may be erased by injecting holes into the charge trap layer 125. In the semiconductor device 100, by using the channel layer 115 that is ambipolar, deterioration of worst on current may be reduced, and mobility may be improved even when the stack number increases in the vertical direction. The aluminum oxide layer of the pillar 112 may improve the mobility of the channel layer 115 as well as thermal stability, and accordingly, the channel layer 115 may have ambipolarity. In the channel layer 115, (electron mobility)/(hole mobility) may have a range from 0.01 to 100. As the channel layer 115 has ambipolarity, the electron mobility may be greater than the hole mobility, and the hole mobility may be greater than the electron mobility. The pillar 112 may include, for example, Al₂O₃.

To increase the thermal stability of the channel layer 115, the channel layer 115 may include a dopant at 5 at % or less. The dopant may have ionic valency of 2 and may include an element having a value of Gibbs formation energy at room temperature in a range from (−600) kJ/mol to (−250) kJ/mol. The dopant may include at least one of Ni, Cu, Ge, Cd, Sn, and Pb.

The charge-tunneling layer 124 may be a layer in which charge tunneling occurs and may include, for example, at least one of a silicon oxide, a silicon oxynitride, and a metal oxide; however, the disclosure is not limited thereto. The charge-tunneling layer 124 may include, for example, at least one of SiO, SiON, SiOCN, HfSiO, AlSiO, HfSiON, and AlSiON.

The gate electrodes 131 may be stacked apart from each other in the direction perpendicular to the substrate 101, and the spacer layers 132 may be arranged between the gate electrodes 131. The spacer layer 132 may include an insulating material and may separate the gate electrodes 131 such that the gate electrodes 131 may be driven independently on a memory cell MC basis. Although FIG. 1 does not illustrate a source electrode and a drain electrode, FIG. 2A illustrates a source electrode 110 and a drain electrode 140. The source electrode 110 and the drain electrode 140 may be electrically connected to the channel layer 115. The source electrode 110 may be arranged under the channel layer 115, and the drain electrode 140 may be arranged on the channel layer 115. However, the disclosure is not limited thereto, and the positions of the source electrode 110 and the drain electrode 140 may be changed. The drain electrode 140 may be connected to a bit line. The source electrode 110 and the drain electrode 140 may include a material having a work function in a range greater than 0 eV and less than or equal to 5 eV. The source electrode 110 and the drain electrode 140 may include, for example, at least one of Ru, W, Mo, Co, Ti, TiN, WN, MoN, ITO, AZO, and ZnO.

Although FIG. 2A illustrates that the source electrode 110 is connected to one cell string CS, the source electrode 110 may be commonly connected to each cell string CS.

In regard to the overall structure, the channel layer 115 may surround a lateral surface of the pillar 112, the charge-tunneling layer 124 may surround a lateral surface of the channel layer 115, and the charge trap layer 125 may surround a lateral surface of the charge-tunneling layer 124. The first charge-blocking layer 126 may surround a lateral surface of the charge trap layer 125.

Each channel corresponding to the gate electrode 131 may be formed in the channel layer 115 between the source electrode 110 and the drain electrode 140. When a certain voltage is applied to the gate electrode 131 in each memory cell MC, charges flowing between the source electrode 110 and the drain electrode 140 in the channel layer 115 corresponding to the gate electrode 131 may pass through the charge-tunneling layer 124 and may be trapped in the charge trap layer 125, thereby storing information. The memory cell MC may operate as a single transistor, and information may be recorded through a threshold voltage change of a transistor.

The gate electrode 131 may control the corresponding channel layer 115, and a word line may be electrically connected to the gate electrode 131. The gate electrode 131 may include a metal material having excellent electric conductivity, a conductive oxide, a metal nitride, silicon doped with impurities, a two-dimensional (2D) conductive material, etc. The metal material and the metal nitride may include, for example Au, Ti, TiN, TaN, W, Mo, WN, Pt, Ni, or any combination thereof. The conductive oxide may include, for example, indium tin oxide (ITO), indium zinc oxide (IZO), etc. However, this is just an example, the gate electrode 131 may include various other materials. The spacer layer 132 may insulate and separate the gate electrodes 131 from each other. The spacer layer 132 may include, for example, a silicon oxide, a silicon nitride, a metal organic framework, or a boron nitride. The metal organic framework may include a porous solid material which is synthesized by self-assembly based on a meatal node and an organic ligand. The metal organic framework may include, for example, UiO-66 or ZIF-8. The boron nitride may include amorphous BN or amorphous BCN.

The first charge-blocking layer 126 may serve as a barrier blocking the charge migration between the charge trap layer 125 and the gate electrode 131. One surface of the first charge-blocking layer 126 may be in contact with the charge trap layer 125, and another surface of the first charge-blocking layer 126 may be in contact with the gate electrode 131.

The charge trap layer 125 may store inflow charges. Charges presents in the channel layer 115 may flow into the charge trap layer 125 by the tunneling effect, etc. Charges which have flowed into the charge trap layer 125 may be fixed in the charge trap layer 125.

The charge trap layer 125 may be formed by spinodal decomposition through heat treatment. The spinodal decomposition may occur when formation energy (e.g., Gibbs free-energy change (ΔG)) by mixing of materials constituting the charge trap layer 125 is greater than 0. The spinodal decomposition may be controlled by a heat treatment temperature for the materials of the charge trap layer 125.

The reliability element, which may be a key requirement in a semiconductor device, relates to retention of data, e.g., characteristics of storing charges in the charge trap layer 125 for a long time. When a distance between the memory cells MC is reduced to increase the density of memory in a semiconductor device, migration of charges trapped between the memory cells MC may occur, which may lead to degradation of charge retention characteristics.

Charges may migrate from the charge trap layer 125 to the charge-tunneling layer 124 through trap-assisted tunneling or thermal emission. A degree of such migration of charges may be determined by a conduction band offset (CBO) at an interface of the charge trap layer 125 and the charge-tunneling layer 124.

In a direction parallel with the charge trap layer 125, charge migration may be caused by lateral migration according to a gradient of the charge concentration. The charge migration in the direction parallel with the charge trap layer 125 may be controlled by Poole-Frenkel tunneling. The current density by the Poole-Frenkel tunneling may be represented by Poole-Frenkel Conduction Equation (Equation 1):

$$J = q μ {N}_{c} E exp ( \frac{- q ( {E}_{T} - \sqrt{q E / πε} )}{k T} ) \qquad ( equation 1 )$$

$$( J \text{:} current density , q \text{:} electronic charge , μ \text{:} carrier mobility Nc \text{:} density of states in conduction band , E \text{:} electric field , ET \text{:} trap energy , ε \text{:} permittivity , k \text{:} Boltzmann constant , T \text{:} temperature ) .$$

The charge migration in the direction parallel with the charge trap layer 125 due to the Poole-Frenkel tunneling may be determined by the trap energy (E_{T}) and the trap density (N_{T}) in the charge trap layer 125. The trap energy means a voltage barrier that electrons need to pass through to migrate from one atom to another atom in a material. That is, the trap energy may refer to a depth of a trap state with respect to a conduction band minimum (CBM) of a material. The trap density refers to the number of charges trapped per unit volume. The trap density may be calculated by using the charge pumping method. The charge retention characteristics in the direction parallel with the charge trap layer 125 may be improved by higher trap energy and higher trap density.

The charge trap layer 125 may include, for example, at least one of silicon nitride (SiN), silicon nitride (SiON), gallium nitride (GaN), gallium oxide (GaO), hafnium oxide (HfO), hafnium aluminum oxide (HfAlO), hafnium silicon oxide (HfSiO), scandium oxide (ScO), strontium oxide (SrO), zirconium oxide (ZrO), zirconium silicon oxide (ZrSiO), zirconium aluminum oxide (ZrAlO), yttrium oxide (YO), tantalum oxide (TaO), barium oxide (BaO), and zinc sulfide (ZnS).

Alternatively, the charge trap layer 125 may include a matrix and nano crystals in the matrix. The matrix may include an amorphous metal oxynitride. The matrix may include a metal oxynitride having a greater permittivity than a silicon nitride. For example, the matrix may include at least one of AlON, ZrON, LaON, AlSiON, HfAlON, LaSiON, AlZrON, LaAlON, HfAlON, and ZrSiON. However, the disclosure is not limited thereto. For example, the nano crystals may include at least one of AlN, GaN, GeN, SiN, CN, InN, YN, ScN, and ZrN. However, the disclosure is not limited thereto.

As the charge trap layer 125 includes an amorphous metal oxynitride in which nano crystals having semiconductor characteristics are dispersed, the trap energy and the trap density may increase, and the charge retention characteristics may be improved by limiting and/or suppressing the migration of charges trapped between the memory cells MC. Accordingly, a reduced threshold voltage may improve memory operation characteristics.

The first charge-blocking layer 126 may limit and/or prevent leakage of charges over the charge trap layer 125 to the spacer layer 132 and the gate electrode 131. The first charge-blocking layer 126 may include a silicon oxide, a metal oxide, or a metal nitride; however, the disclosure is not limited thereto. The first charge-blocking layer 126 may include at least one of an aluminum oxide, a magnesium oxide, an aluminum nitride, and a gallium nitride. The first charge-blocking layer 126 may include, for example, SiO₂, SiON, or Al₂O₃.

The semiconductor device 100 may adjust the conductance of the channel layer 115 through the gate electrode 131. In this regard, the charge carrier density adjustable at a driving voltage of 6 V may be about 1.5×10¹⁹/cm³. Considering the fermi-dirac distribution at a bandgap, to meet the charge carrier density, the bandgap may be 2.2 eV or less. The channel layer 115 may satisfy such bandgap conditions and may include at least one of SnO, Cu₂O, CoO, FeO, NiO, and VO₂. For example, the electron mobility may be up to 280 cm²/Vs, and the hole mobility may be up to 60 cm²/Vs. In this manner, the channel layer 115 may have stable ambipolar characteristics.

FIG. 2B illustrates an example in which a pillar 112′ and a gate stack 120′ are changed in the cell string CS illustrated in FIG. 2A. As components in FIG. 2B that are denoted by the same reference numeral as in FIG. 2A have substantially the same configuration and operational effects, detailed descriptions thereon are omitted.

Referring to FIG. 2B, the gate stack 120′ may include the charge-tunneling layer 124 arranged on the channel layer 115, the charge trap layer 125, the first charge-blocking layer 126, and a second charge-blocking layer 127. The second charge-blocking layer 127 may surround some surfaces of the gate electrode 131. In FIG. 2B, the second charge-blocking layer 127 may surround three surfaces of the gate electrode 131. The second charge-blocking layer 127 may reduce leakage of charges over the charge trap layer 125 to the gate electrode 131. The second charge-blocking layer 127 may include at least one of an aluminum oxide, a hafnium oxide, and a zirconium oxide.

The pillar 112′ may include an aluminum oxide layer 112a arranged on an inner side the channel layer 115 and a silicon oxide layer 112b arranged on an inner side of the aluminum oxide layer 112a. The aluminum oxide layer 112a may be in direct contact with the channel layer 115. The aluminum oxide layer 112a may have a cylindrical shell structure. The aluminum oxide layer 112a may improve the mobility of the channel layer 115 as well as thermal stability, and accordingly, the channel layer 115 may have ambipolarity. The aluminum oxide layer 112a may have a crystal structure. The silicon oxide layer 112b may have a cylindrical structure. However, the disclosure is not limited thereto. The silicon oxide layer 112b may improve the mobility of the channel layer 115.

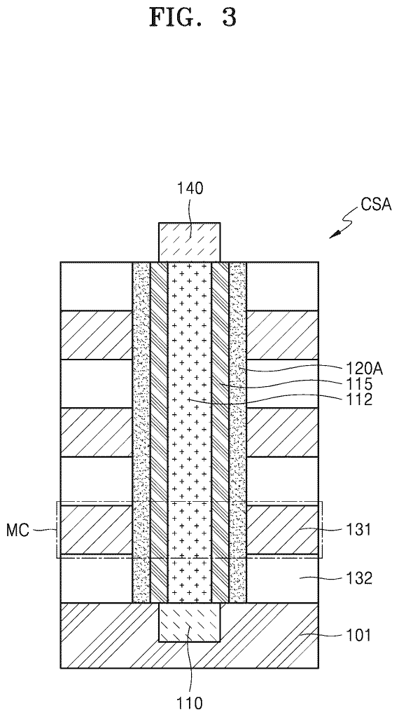

FIG. 3 illustrates an example in which a gate stack 120A is changed as compared to FIG. 2A. As components in FIG. 3 that are denoted by the same reference numeral as in FIG. 2A have substantially the same configuration and operational effects, detailed descriptions thereon are omitted.

A cell string CSA may include the gate stack 120A, and the gate stack 120A may include a ferroelectric material layer or an anti-ferroelectric material layer. The ferroelectric material layer or the anti-ferroelectric material may have ferroelectric characteristics based on a crystalline substance. The ferroelectric material is a material having ferroelectricity which maintains spontaneous polarization by aligning electric dipole moments even when no electric field is applied thereto. The ferroelectric material may show spontaneous polarization by permanent dipole moments aligned in the same direction. The ferroelectric material may have remnant polarization by dipole even in a state where there is no external electric field. Moreover, a polarization direction may switch according to a domain unit by an external electric field. The threshold voltage of the semiconductor device 100 may change according to the switching of the polarization direction of the ferroelectric material, for example, from the gate electrode 131 towards the channel layer 115 or from the channel layer 115 towards the gate electrode 131. The channel layer 115 may include the material A and oxygen, and the material A may include at least one of tin, cobalt, steel, nickel, copper, and vanadium. Accordingly, the channel layer 115 may have ambipolarity.

The anti-ferroelectric material may include an array of electric dipoles; however, the remnant polarization may be 0 or close to 0. In a state where there is no electric field, as directions of adjacent dipoles are opposite to each other, and the polarization is offset, the spontaneous polarization and remnant polarization may be 0 or close to 0. However, when an external electric field is applied, polarization characteristics and switching characteristics may be shown.

The ferroelectric material may include a hafnium oxide material or an aluminum nitride material. The ferroelectric material may have a structure in which a dopant is injected into a hafnium oxide-based material or a structure in which a dopant is injected into an aluminum nitride-based material. When the ferroelectric material is a hafnium oxide-based material, the dopant may be Zr, La, Al, Si, or Y. When the ferroelectric material is an aluminum nitride-based material, the dopant may be B or Sc.

The ferroelectric material may have at least one of a fluorite structure, a perovskite structure, and a wurtzite structure.

The ferroelectric material having a fluorite structure may include, for example, HfO₂ or ZrO₂. HfO₂ or ZrO₂ may have a crystal structure of tetragonal system or a crystal structure of orthorhombic system. The crystal structure of tetragonal system may have anti-ferroelectricity, and the crystal structure of orthorhombic system may have ferroelectricity. Undoped HfO₂ may have the stable crystal structure of tetragonal system or may have the crystal structure of orthorhombic system, depending on the size of crystal grain. Undoped ZrO₂ may have the stable crystal structure of tetragonal system. Undoped HfO₂ or ZrO₂ may include nano crystals having a grain size of about 1 nm to about 3 nm; however, the disclosure is not limited thereto.

The fluorite-based material may include, for example, HfO₂ or ZrO₂ including a dopant. The dopant may include, for example, at least one of Al, Ga, Co, Ni, Mg, In, La, Y, Nd, Sm, Er, Sr, Ba, Gd, Ge, N, and Si. However, this is only an example. HfO₂ or ZrO₂ including a dopant may have the crystal structure of tetragonal system having anti-ferroelectricity or the crystal structure of orthorhombic system according to the grain size and doping concentration. When the grain size is small, and the doping concentration is high, the crystal structure of tetragonal system may be stable, and when the grain size is great, and the doping concentration is low, the crystal structure of orthorhombic system may be stable.

HfO₂ or ZrO₂ doped with a dopant may include nanocrystals having a greater grain size than the undoped HfO₂ or ZrO₂. For example, HfO₂ or ZrO₂ doped with a dopant may have a grain size of about 4 nm to about 7 nm or about 4 nm to about 5 nm; however, the disclosure is not limited thereto.

The dopant concentration may vary according to a type of dopant. For example, when the dopant is Si, the doping concentration may be about 1 at % (atomic percent) to about 5 at %. However, the disclosure is not limited thereto.

The ferroelectric material having a perovskite structure may include a material having an M¹M²O₃ composition wherein M¹M² represents a metal element. The perovskite-based material may include, for example, at least one of PbZrO₃, PbTiO₃, BaTiO₃, SrTiO₃, and CaTiO₃. However, the disclosure is not limited thereto. The perovskite-based material may have the crystal structure of tetragonal system having anti-ferroelectricity or the crystal structure of orthorhombic system having ferroelectricity according to a composition ratio of constituent elements.

The wurtzite-based material may include undoped AlN, GaN, or InN or may include AlN, GaN, or InN each including a dopant. The dopant may include at least one of boron (B) or scandium (Sc).

For example, the gate stack 120A may include a hafnium zirconium oxide, and Zr/(Hf+Zr) may have a range from about 20 at % to about 90 at %. The gate stack 120A may include at least one of TiN, W, Mo, Ru, Pt, and Y at the interface between the gate stack 120A and the channel layer 115.

As the gate stack 120A includes a ferroelectric material or an anti-ferroelectric material, the cell string CSA may be applied to an ambipolar ferroelectric VNAND. Although FIG. 3 illustrates an example in which the gate stack 120A includes a single layer, a channel interlayer including at least one of SiO, SiON, SiN, AlO, HfO, and ZrO may be further arranged between the channel layer 115 and the ferroelectric material layer, or a gate interlayer including at least one of SiO, SiON, SiN, and AlO may be further arranged between the ferroelectric material layer and the gate electrode 131. In addition, although FIG. 3 illustrates an example in which the pillar 112 includes a single layer, the pillar 112 may be replaced with the pillar 112′ including two layers (112a and 112b) as illustrated in FIG. 2B.

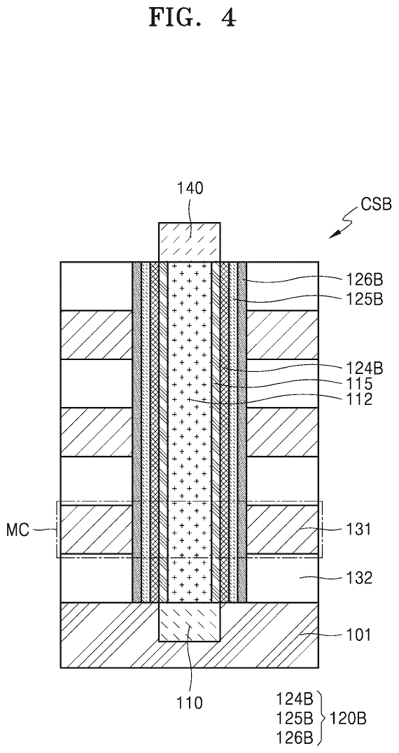

FIG. 4 illustrates an example in which a gate stack 120B is changed as compared to FIG. 2A. As components in FIG. 4 that are denoted by the same reference numeral as in FIG. 2A have substantially the same configuration and operational effects, detailed descriptions thereon are omitted.

A cell string CSB may include the gate stack 120B, and the gate stack 120B may include an electrolyte layer 124B arranged on a sidewall of the channel layer 115, an electrochemical layer 125B arranged on a sidewall of the electrolyte layer 124B, and a charge-blocking layer 126B arranged on a sidewall of the electrochemical layer 125B.

The electrolyte layer 124B may include at least one of hafnium oxide (HfO), zirconium oxide (ZrO), lanthanum oxide (LaO), gallium oxide (GaO), tantalum oxide (TaO), and titanium oxide (TiO). The electrochemical layer 125B may include at least one of HfZrO, HfSiO, and HfAlO. The electrochemical layer 125B may have oxygen vacancy and may include an amorphous structure. The charge-blocking layer 126B may include at least one of silicon oxide (SiO), silicon oxynitride (SiON), silicon nitride (SiN), aluminum oxide (AlO), hafnium oxide (HfO), tantalum oxide (TaO), and zirconium oxide (ZrO).

The cell string CSB may be applied to an electrochemical VNAND, and due to the oxygen vacancy or oxygen ion migration between the channel layer 115 and the gate stack 120B, an on current or a threshold voltage Vₜₕ of a transistor may change.

Although FIG. 4. illustrates an example in which one pillar 112 includes a single layer, the pillar 112 may be replaced with the pillar 112′ including two layers (112a and 112b) as illustrated in FIG. 2B. In addition, the charge-blocking layer 126B may be replaced with two charge-blocking layers (126 and 127) as illustrated in FIG. 2B. In FIG. 4, the electrolyte layer 124B may be provided optionally.

As described above, in the semiconductor device 100 according to an embodiment, the channel layer 115 may include an ambipolar oxide semiconductor to secure improved thermal stability and/or higher mobility of ambipolar oxide semiconductor. The semiconductor device 100 may be applied to an ambipolar non-volatile memory device.

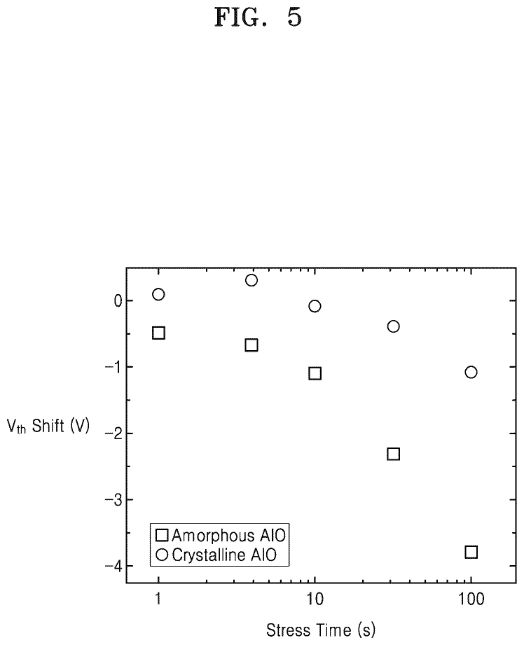

FIG. 5 shows a threshold voltage Vₜₕ shift according to stress time of the semiconductor device 100, according to an embodiment. In this case, the pillar 112 of the semiconductor device 100 may include an aluminum oxide layer, the channel layer 115 may include a tin oxide (SnO), and the source electrode 110 and the drain electrode 140 may include ITO. When the threshold voltage Vₜₕ is close to 0, the semiconductor device 100 may be stable. When the aluminum oxide layer has a crystal structure or an amorphous structure, both cases show stable characteristics. The case where the aluminum oxide layer has a crystal structure shows more stable characteristics than the case where the aluminum oxide layer has an amorphous structure.

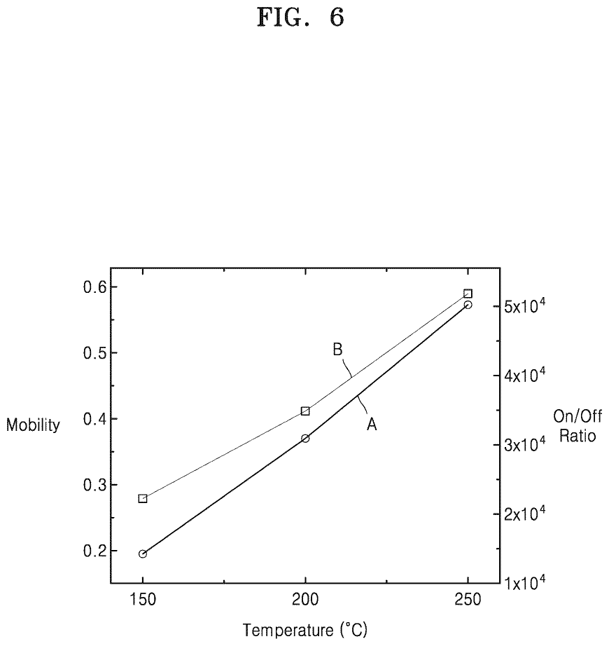

FIG. 6 shows a mobility and an on/off ratio according to a deposition temperature of the semiconductor device 100, according to an embodiment. Graph A shows a mobility, and graph B shows an on/off ratio. Referring to FIG. 6, even when the temperature is high, the mobility and on/off ratio is high.

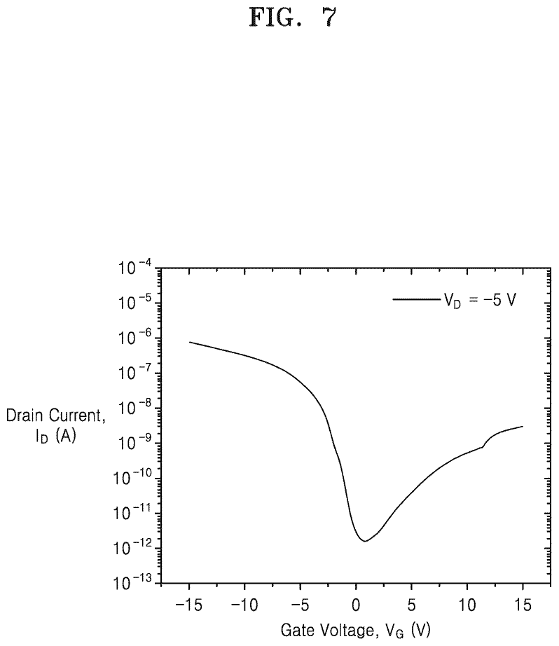

FIG. 7 shows a drain current I_{D} according to a gate voltage V_{G} of the semiconductor device 100. In this regard, the drain voltage may be −5 V. FIG. 7 exhibits the ambipolar characteristics in which a drain current is shown at both of a negative voltage and a positive voltage. As such, the semiconductor device 100 according to an embodiment may have ambipolar characteristics and may show higher mobility and/or improved thermal stability.

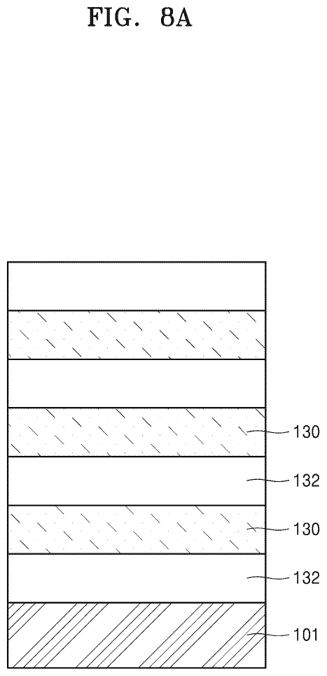

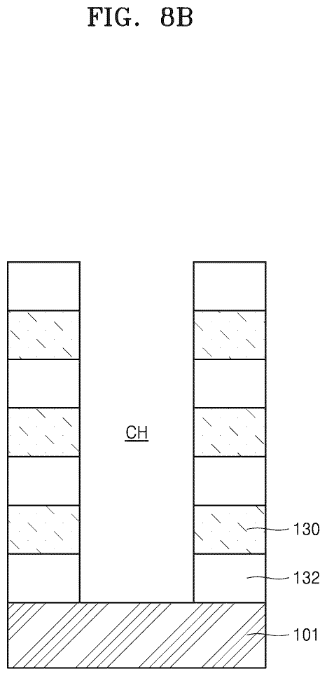

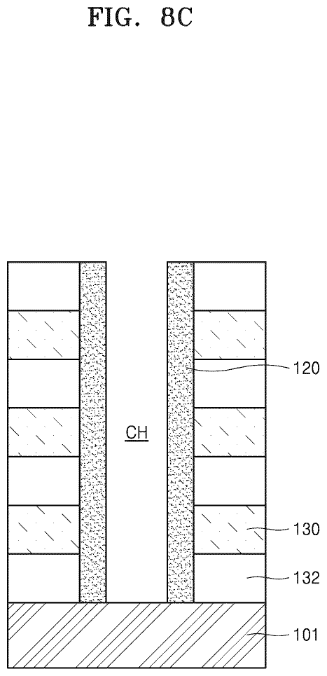

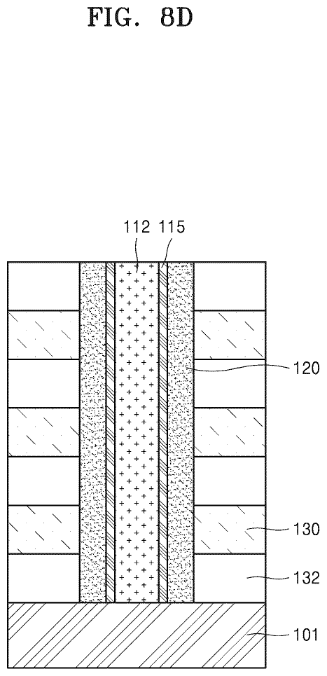

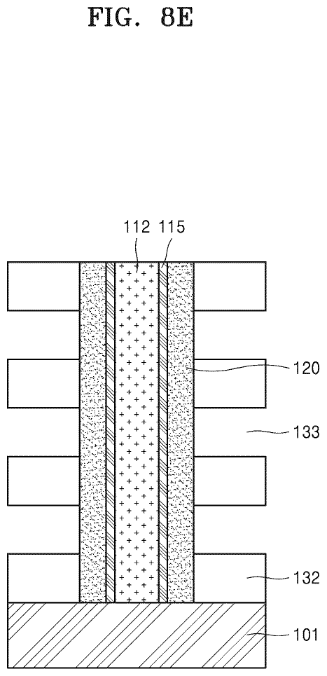

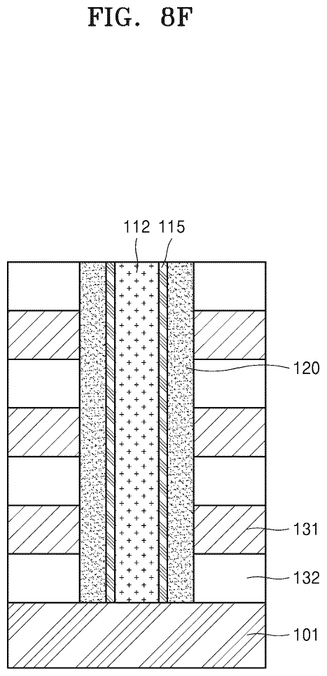

Next, a method of manufacturing a semiconductor device according to an embodiment is described with reference to FIGS. 8A to 8F.

Referring to FIG. 8A, a sacrificial layer 130 and the spacer layer 132 may be alternately stacked on the substrate 101. The spacer layer 132 may include, for example, a silicon oxide, a silicon nitride, etc.; however, the disclosure is not limited thereto. The spacer layer 132 may include, for example, SiO₂. The sacrificial layer 130 may include, for example, a silicon nitride.

Referring to FIG. 8B, the channel hole CH may be formed to penetrate the stack of the spacer layer 132 and the sacrificial layer 130. The channel hole CH may be formed to extend in the direction perpendicular to the surface of the substrate 101. The channel hole CH may have a circular cross-section. The channel hole CH may be formed by anisotropically etching the spacer layer 132 and the sacrificial layer 130.

Referring to FIG. 8C, the gate stack 120 may be formed in the channel hole CH. The gate stack 120 may have a single-layer structure or a multi-layer structure. The gate stack 120 may be formed by a physical vapor deposition method, a chemical vapor deposition method, or an atomic layer deposition method. The gate stack 120 may include the first charge-blocking layer 126, the charge trap layer 125, and the charge-tunneling layer 124, which may be formed sequentially on an inner side of the channel hole CH as illustrated in FIG. 2A. Alternatively, the gate stack 120 may include a ferroelectric material layer such as the gate stack 120A as illustrated in FIG. 3. Alternatively, the gate stack 120 may include the electrolyte layer 124B, the electrochemical layer 125B arranged on the sidewall of the electrolyte layer 124B, and the charge-blocking layer 126B arranged on the sidewall of the electrochemical layer 125B as illustrated in FIG. 4.

Referring to FIG. 8D, the channel layer 115 may be formed on the sidewall of the gate stack 120. The channel layer 115 may include the material A and oxygen, and the material A may include at least one of tin, cobalt, steel, nickel, copper, and vanadium. The channel layer 115 may be formed by a physical vapor deposition method, a chemical vapor deposition method, or an atomic layer deposition method. The pillar 112 may be formed on the channel layer 115. The pillar 112 may include an aluminum oxide layer in direct contact with the channel layer 115.

Referring to FIG. 8E, the sacrificial layer 130 may be removed by selective etching. Even when the sacrificial layer 130 is removed, the spacer layer 132 may be supported by the gate stack 120. Referring to FIGS. 8E and 8F, the gate electrode 131 may be formed in a space 133 from which the sacrificial layer 130 has been removed. In this manner, the gate electrode 131 and the spacer layer 132 may be stacked alternately.

The ambipolar semiconductor device may be manufactured by the method of manufacturing a semiconductor device according to an embodiment.

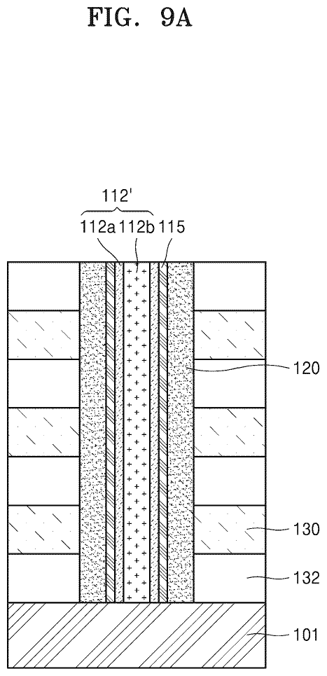

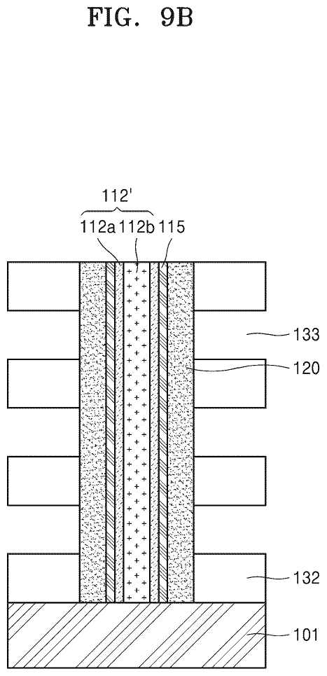

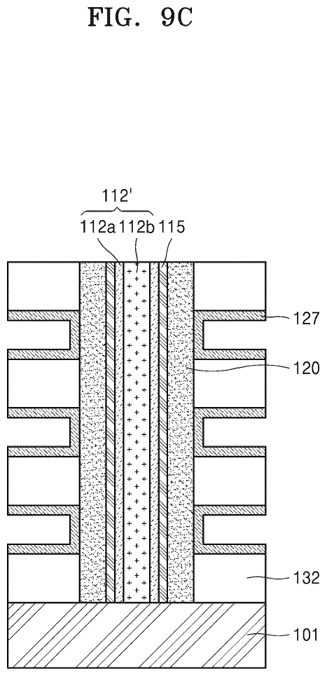

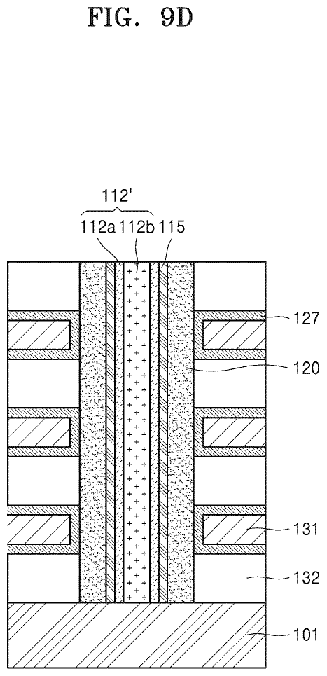

FIGS. 9A to 9D are diagrams illustrating a method of manufacturing the semiconductor device illustrated in FIG. 2B.

To avoid redundancy, a method of manufacturing a semiconductor device may be described by referring to FIG. 9A in addition to the description provided in relation to FIGS. 8A, 8B, and 8C.

Referring to FIG. 9A, the aluminum oxide layer 112a may be arranged on an inner sidewall of the channel layer 115, and the silicon oxide layer 112b may be formed on an inner sidewall of the aluminum oxide layer 112a. The pillar 112′ may include two layers, which may include the aluminum oxide layer 112a and the silicon oxide layer 112b.

Referring to FIG. 9B, the sacrificial layer 130 may be removed by selective etching. Referring to FIG. 9C, the second charge-blocking layer 127 may be formed in the space 133 from which the sacrificial layer 130 has been removed. The second charge-blocking layer 127 may be formed thin on an inner sidewall of the space 133 from which the sacrificial layer 130 has been removed. Referring to FIG. 9D, the gate electrode 131 may be formed on the second charge-blocking layer 127. In this manner, a semiconductor device including the first charge-blocking layer 126 and the second charge-blocking layer 127 may be manufactured.

When the gate stack 120 includes a ferroelectric material layer as illustrated in the gate stack 120A in FIG. 3, forming of the gate stack 120 may include forming a ferroelectric precursor layer and heat-treating the ferroelectric precursor layer. The ferroelectric precursor layer may be a layer of ferroelectric material before crystallization. The ferroelectric precursor layer may be formed by a physical vapor deposition method, a chemical vapor deposition method, or an atomic layer deposition method. The gate stack (see gate stack 120A in FIG. 3) may have a ferroelectric phase by the heat treatment process. The heat treatment process may be performed at a temperature range from about 400° C. to about 1,000° C. or from about 420° C. to about 800° C. Alternatively, the gate stack 120 may include the gate stack 120B with the electrolyte layer 124B, the electrochemical layer 125B arranged on the sidewall of the electrolyte layer 124B, and the charge-blocking layer 126B arranged on the sidewall of the electrochemical layer 125B as illustrated in FIG. 4.

The semiconductor device 100 according to an embodiment may include a plurality of memory cells MC which maintain information even when the power supply is discontinued, and the stored information may become available again when the power is resupplied. Such semiconductor device 100 may be widely applied to a cell phone, a digital camera, a personal digital assistant (PDA), a mobile computer apparatus, etc.

FIG. 10 is a circuit diagram including a semiconductor device according to an embodiment. The semiconductor device may be a non-volatile memory device. k*n cell strings CS may be arranged in a matrix and may be denoted by CSij according to a row and a column (1≤i≤k, 1≤j≤n). Each cell string CSij may be connected to a bit line BL, a string select line SSL, a word line WL, and a common source line CSL.

Each cell string CSij may include memory cells MC and a string select transistor SST. The memory cells MC and the string select transistor SST of each cell string CSij may be stacked in the height direction.

Rows of the plurality of cell strings CS may respectively be connected to different string select lines (SSL1 to SSLk) from each other. For example, the string select transistors SST of the cell strings CS11 to CS1n may be commonly connected to the string select line SSL1. The string select transistors SST of the cell strings CSk1 to CSkn may be commonly connected to the string select line SSLk.

Columns of the plurality of cell strings CS may respectively be connected to different bit lines (BL1 to BLn) from each other. For examples, the memory cells MC and the string select transistors SST of the cell strings CS11 to CSk1 may be commonly connected to the bit line BL1, and the memory cells MC and the string select transistors SST of the cell strings CS1n to CSkn may be commonly connected to the bit line BLn.

The rows of the plurality of cell strings CS may be respectively connected to different common source lines (CSL1 to CSLk) to each other. For example, the string select transistors SST of the cell strings CS11 to CS1n may be commonly connected to the common source line CSL1, and the string select transistors SST of the cell strings CSk1 to CSkn may be commonly connected to the common source line CSLk.

The memory cells MC located at the same height from the string select transistors SST or the substrate may be commonly connected to one word line WL, and the memory cells MC located at different heights from each other may respectively be connected to different word lines (WL1 to WLn) from each other.

The circuit structures illustrated in the drawings are just an example. For example, the number of rows of the cell strings CS may increase or decrease. When the number of rows of the cell strings CS changes, the number of string select lines connected to the rows of the cell strings CS and the number of cell strings CS connected to one bit line BL may also change. When the number of rows of the cell strings CS changes, the number of common source lines connected to the rows of the cell strings CS may also change.

The number of columns of the cell strings CS may also increase or decrease. When the number of columns of the cell strings CS changes, the number of bit lines BL connected to the columns of the cell strings CS and the number of cell strings CS connected to one string select line may also change.

The height of the cell strings CS may also increase or decrease. For example, the number of memory cells MC stacked in each cell string CS may increase or decrease. When the number of memory cells MC stacked in each cell string CS changes, the number of word lines WL may also change. For example, the number of string select transistors provided to each cell string CS may increase. When the number of string select transistors provided to each cell string CS changes, the number of string select lines or common source lines may also change. When the number of string select transistors SST increases, the string select transistors SST may be stacked in the same manner as the memory cells MC.

For example, the reading and writing may be performed by the unit of row of the cell strings CS. The cell strings CS may be selected as a row unit by the common source line CSL, and the cell strings CS may be selected as a row unit by the string select line SSL. In addition, a voltage may be applied to at least two common source lines CSL as a unit. Alternatively, a voltage may be applied to the all of common source lines CSL as a unit.

The reading and writing may be performed by the page at a selected row of the cell strings CS. The page may be a row of the memory cells connected to one word line WL. At a selected row of the cell strings CS, the memory cells may be selected by the word lines WL by the unit of page. For example, the gate electrode 131 of FIG. 1 may be connected to one of the word line WL and the string select line SSL.

The memory cell MC may have a circuit structure in which a transistor including the gate electrode 131, the spacer layer 132, and the channel layer 115 is connected to the charge trap layer 125.

Such memory cell MC may be arranged continuously in the vertical direction (Z direction) to constitute the cell string CS. In addition, both ends of the cell string CS may be connected to the common source line CSL and the bit line BL as illustrated in the circuit diagram of FIG. 10. By applying a voltage to the common source line CSL and the bit line BL, a program, a reading process, a deleting process may be performed on the plurality of memory cells MC.

For example, when a memory cell MC for writing is selected, a gate voltage value of the memory cell may be adjusted such that no channel is formed in the selected memory cell (channel-off), and a gate voltage value of unselected memory cells may also be adjusted to channel-on the unselected memory cells. Accordingly, charges may tunnel through the charge-tunneling layer 124 by the voltage applied to the common source line CSL and the bit line BL and may be stored in the charge trap layer 125 of the selected memory cell MC. Then, desired information of 1 or 0 may be written onto the selected memory cell MC.

Similar to the above, in the reading operation, the reading may be performed on a selected cell. That is, the gate voltages applied to the gate electrodes 131 may be adjusted to channel on the selected memory cell MC and channel off the unselected memory cells MC, and then, a current flowing in the memory cell MC by an applied voltage Vread between the common source line CSL and the bit line BL may be measured to identify a memory cell state (1 or 0).

The semiconductor device 100 may have a structure in which cells are connected to each other in the vertical direction. When information is stored, charges may diffuse in the vertical direction and move to adjacent cells to affect operations of the adjacent cells. However, in the semiconductor device 100 as the charge trap layer 125 includes a nanocrystal area and an isolation area to suppress a lateral charge loss, negative effects on operations of adjacent cells may be reduced.

Semiconductor devices according to example embodiments may be applied to various electronic apparatuses.

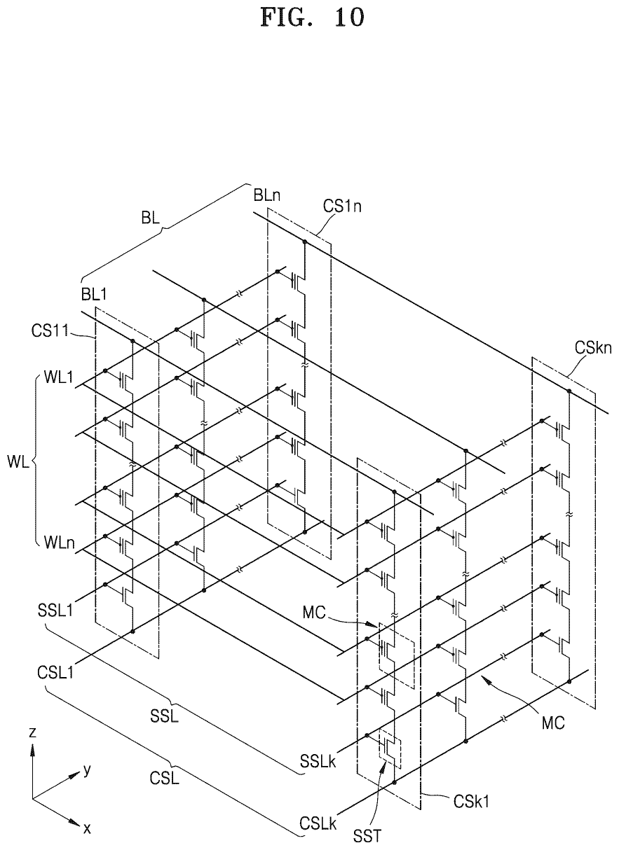

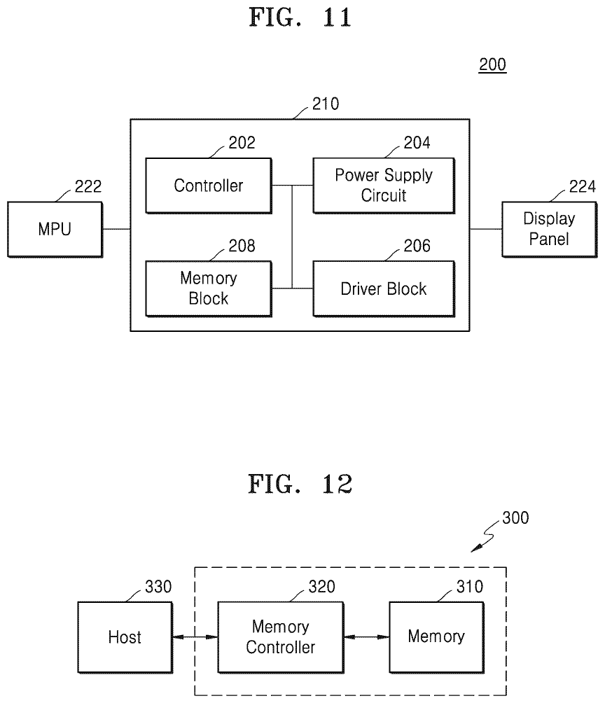

FIG. 11 is a schematic block diagram of a display apparatus 200 including a display driver integrated circuit (DDI) 210 according to an embodiment. Referring to FIG. 11, the DDI 210 may include a controller 202, a power supply circuit 204, a driver block 206, and a memory block 208. The controller 202 may receive and decode a command applied from a main processing unit (MPU) 222 and control each block of the DDI 210 to implement an operation according to the command. The power supply circuit 204 may generate a driving voltage in response to the control by the controller 202. In response to the control by the controller 202, the driver block 206 may drive a display panel 224 by using the driving voltage generated from the power supply circuit 204. The display panel 224 may be, for example, a liquid crystal display panel, an organic light-emitting device (OLED) display panel, or a plasma display panel. The memory block 208, as a block temporarily storing commands input to the controller 202 or control signals output from the controller 202 or storing required data, may include a memory device such as RAM, ROM, DRAM, NAND, etc. For example, the memory block 208 may include the semiconductor device 100 according to the embodiments described above.

FIG. 12 is a block diagram of an electronic apparatus 300 according to an embodiment. Referring to FIG. 12, the electronic apparatus 300 may include a memory 310 and a memory controller 320. In response to a request from a host 330, the memory controller 320 may control the memory 310 to read data from the memory 310 and/or write data onto the memory 310. The memory 310 may include the semiconductor device 100 according to the embodiments described above.

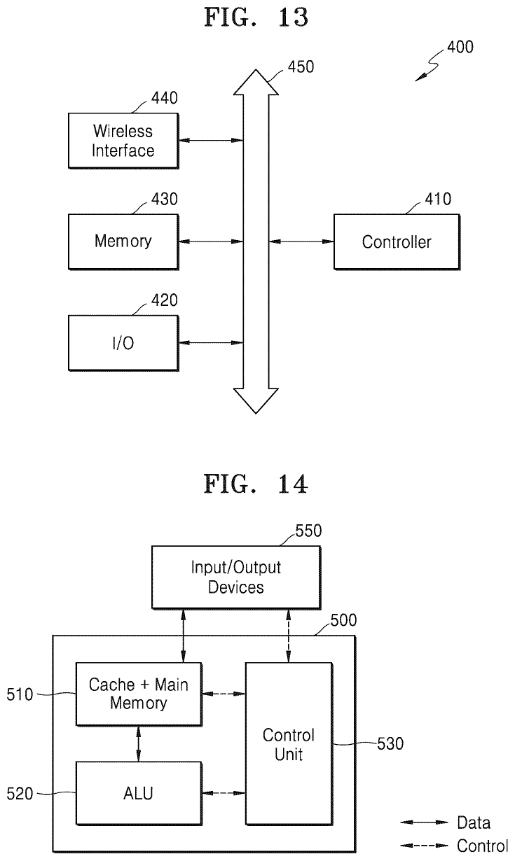

FIG. 13 is a block diagram of an electronic apparatus 400 according to an embodiment. Referring to FIG. 13, the electronic apparatus 400 may constitute a wireless communication apparatus or an apparatus capable of transmitting and/or receiving information in a wireless environment. The electronic apparatus 400 may include a controller 410, an input/output apparatus (I/O) 420, a memory 430, and a wireless interface 440, which are interconnected to each other through a bus 450.

The controller 410 may include a microprocessor, a digital signal processor, or at least one of process apparatuses of a similar kind. The I/O 420 may include at least one of a keypad, a keyboard, and a display. The memory 430 may be used to store a command executed by the controller 410. For example, the memory 430 may be used to store user data. The electronic apparatus 400 may use the wireless interface 440 to transmit/receive data through a wireless communication network. The wireless interface 440 may include an antenna and/or a wireless transceiver. In some embodiments, the electronic apparatus 400 may be used to a communication interface protocol of a 3rd generation communication system, for example, code division multiple access (CDMA), global system for mobile communications (GSM), north American digital cellular (NADC), extended-time division multiple access (E-TDMA), and/or wide band code division multiple access (WCDMA). The memory 430 of the electronic apparatus 400 may include the semiconductor device 100 according to the embodiments described above.

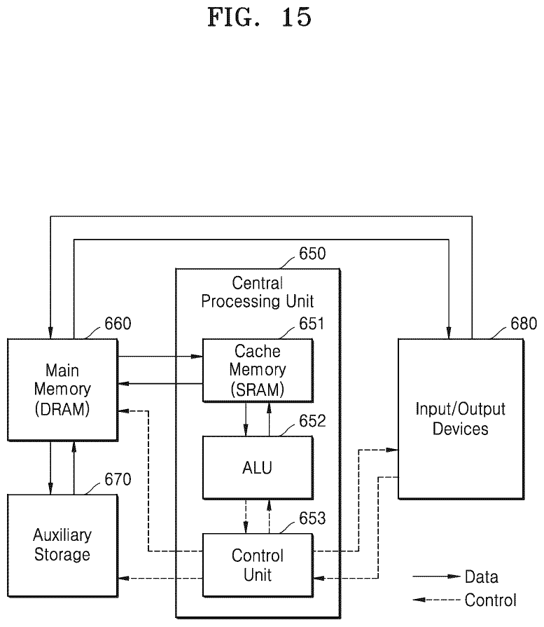

FIGS. 14 and 15 are each a conceptual diagram schematically illustrating a device architecture applicable to an electronic apparatus according to an embodiment.

Referring to FIG. 14 an electronic device architecture 500 may include a memory unit 510 and a control unit 530 and may further include an arithmetic logic unit (ALU) 520. The memory unit 510, the ALU 520, and the control unit 530 may be electrically connected to each other. For example, the electronic device architecture 500 may be implemented as a single chip including the memory unit 510, the ALU 520, and the control unit 530. Specifically, the memory unit 510, the ALU 520, and the control unit 530 may be interconnected by a metal line on an on-chip and communicate directly with each other. The memory unit 510, the ALU 520, and the control unit 530 may be integrated on one substrate (101 of FIG. 1) in a monolithic manner and constitute a single chip. An input/output device 550 (e.g., keyboard, touchpad display) may be connected to the electronic device architecture (chip) 500. The memory unit 510 may include both of a main memory and a cache memory. Such electronic device architecture (chip) 500 may be an on-chip memory processing unit. The memory unit 510, the ALU 520, and/or the control unit 530 may each independently include the semiconductor device 100 according to some embodiments.

Referring to FIG. 15, a cache memory 651, an ALU 652, and a control unit 653 may constitute a central processing unit (CPU) 650, and the cache memory 651 may include static random access memory (SRAM). Separately from the CPU 650, a main memory 660 and an auxiliary storage 670 may be provided, and an input/output device 680 (e.g., keyboard, touchpad display) may be further provided. The main memory 660 may be, for example dynamic random access memory (DRAM) and/or the main memory 660 may include the semiconductor device 100 according to some embodiments.

In some cases, the electronic device architecture may be implemented in a form in which computing unit elements and memory unit elements are adjacent to each other on a single chip without separating sub-units.

The semiconductor device according to some embodiments may be applied to various user apparatus such as a computer, a laptop computer, an ultra mobile personal computer (UMPC), a workstation, a net-book, a personal digital assistant (PDA), a portable computer, a web tablet, a wireless phone, a mobile phone, a smart phone, a digital camera, a digital audio recorder, a digital audio player, a digital picture recorder, a digital picture player, a digital video recorder, a digital video player, an apparatus capable of receiving and transmitting information in a wireless environment, and a home network.

The semiconductor device according to an embodiment may include an oxide semiconductor channel layer to implement ambipolarity. Even when the stack number increases, deterioration of worst on current (WOC) may be reduced, and the mobility may be increased.

A semiconductor device including an ambipolar channel layer may be manufactured by the method of manufacturing a semiconductor device according to an embodiment. The electronic apparatus according to an embodiment may include a highly integrated miniaturized semiconductor device to more stably implement higher capacity and/or improve performance.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a gate electrode and a spacer layer, which are alternately stacked to provide a plurality of gate electrodes and a plurality of spacer layers alternately stacked,
the plurality of gate electrodes and the plurality of spacer layers defining a channel hole penetrating through the plurality of gate electrodes and the plurality of spacer layers;
a gate stack including at least one layer on an inner side of the channel hole;
a channel layer on the gate stack;
a pillar on the channel layer; and
a source electrode and a drain electrode which are electrically connected to the channel layer, wherein
the channel layer includes material A and oxygen,
the material A includes at least one of tin, cobalt, steel, nickel, copper, and vanadium, and
the pillar includes an aluminum oxide layer in contact with the channel layer.

2. The semiconductor device of claim 1, wherein the pillar further includes a silicon oxide layer on the aluminum oxide layer.

3. The semiconductor device of claim 1, wherein,
a material of the channel layer includes A₍₁₋ₓ₎Oₓ,
in A₍₁₋ₓ₎Oₓ, the material A includes at least one of tin, cobalt, steel, and nickel, and
x is in a range from 0.4 to 0.6.

4. The semiconductor device of claim 3, wherein x is in a range from 0.47 to 0.53.

5. The semiconductor device of claim 1, wherein
a material of the channel layer includes A₍₁₋ₓ₎Oₓ,
in A₍₁₋ₓ₎Oₓ, the material A includes copper, and
x is in a range from 0.27 to 0.39.

6. The semiconductor device of claim 1, wherein
a material of the channel layer includes A₍₁₋ₓ₎Oₓ,
in A₍₁₋ₓ₎Oₓ, the material A includes vanadium, and
x is in a range from 0.55 to 0.79.

7. The semiconductor device of claim 1, wherein the source electrode and the drain electrode have a work function greater than 0 eV and less than or equal to 5 eV.

8. The semiconductor device of claim 1, wherein the channel layer further includes a dopant at a content of 5 at % or less.

9. The semiconductor device of claim 8, wherein the dopant includes at least one of Ni, Cu, Ge, Cd, Sn, and Pb.

10. The semiconductor device of claim 1, wherein the at least one of layer of the gate stack includes a charge-tunneling layer on the channel layer, a charge trap layer on the charge-tunneling layer, and a charge-blocking layer on the charge trap layer.

11. The semiconductor device of claim 1, wherein the at least one layer of the gate stack includes a ferroelectric material layer.

12. An electronic apparatus comprising:
a host;
a semiconductor device; and
a memory controller configured to, in response to a request from the host, control the semiconductor device for at least one of data reading from the semiconductor device and data writing to the semiconductor device;
wherein the semiconductor device comprises
a gate electrode and a spacer layer which are alternately stacked to provide a plurality of gate electrodes and a plurality of spacer layers alternately stacked, the plurality of gate electrodes and the plurality of spacer layers defining a channel hole penetrating through the plurality of gate electrodes and the plurality of spacer layers,
a gate stack including at least one layer on an inner side of the channel hole,
a channel layer on the gate stack,
a pillar on the channel layer, and
a source electrode and a drain electrode which are electrically connected to the channel layer, and
wherein the channel layer includes material A and oxygen,
the material A includes at least one of tin, cobalt, steel, nickel, copper, and vanadium, and
the pillar includes an aluminum oxide layer in contact with the channel layer.

13. The electronic apparatus of claim 12, wherein the pillar further includes a silicon oxide layer on the aluminum oxide layer.

14. The electronic apparatus of claim 12, wherein
a material of the channel layer includes A₍₁₋ₓ₎Oₓ,
in A₍₁₋ₓ₎Oₓ, the material A includes at least one of tin, cobalt, steel, and nickel, and
x is in a range from 0.4 to 0.6.

15. The electronic apparatus of claim 14, wherein x is in a range from 0.47 to 0.53.

16. The electronic apparatus of claim 12, wherein
a material of the channel layer includes A₍₁₋ₓ₎Oₓ, and
in A₍₁₋ₓ₎Oₓ, the material A includes copper, and
x is in a range from 0.27 to 0.39.

17. The electronic apparatus of claim 12, wherein
a material of the channel layer includes A₍₁₋ₓ₎Oₓ,
in A₍₁₋ₓ₎Oₓ, the material A includes vanadium, and
x is in a range from 0.55 to 0.79.

18. A method of manufacturing a semiconductor device, the method comprising:
alternately stacking a spacer layer and a sacrificial layer to provide a plurality of spacer layers and a plurality of sacrificial layers alternately stacked;
forming a channel hole to penetrate through the plurality of spacer layers and the plurality of sacrificial layers;
forming a gate stack on an inner side of the channel hole;
forming a channel layer on the gate stack;
forming a pillar on the channel layer;
removing the plurality of sacrificial layers; and
forming a plurality of gate electrodes in spaces from which the plurality of sacrificial layers have been removed,
wherein the channel layer includes material A and oxygen,
the material A includes at least one of tin, cobalt, steel, nickel, copper, and vanadium, and
the pillar includes an aluminum oxide layer in contact with the channel layer.

19. The method of claim 18, wherein, when the channel layer includes A₍₁₋ₓ₎Oₓ and the material A includes at least one of tin, cobalt, steel, and nickel, x includes a range from 0.4 to 0.6.

20. The method of claim 18, wherein
a material of the channel layer includes A₍₁₋ₓ₎Oₓ,
the material A includes copper, and
x is in a range from 0.27 to 0.39.
